(19) United States
(12) Patent Application Publication
(10) Pub. No.: US 2026/0299049 A1
(43) Pub. Date: Oct. 1, 2026

(54) COMPREHENSIVE DETECTION AND ANALYSIS APPARATUS FOR CABLE TERMINAL OF PHOTOVOLTAIC POWER STATION

(71) Applicants: China Railway Seventh Bureau Group Electrical Engineering Co., Ltd., Zhengzhou (CN); China Railway Seventh Bureau Group Co., Ltd., Zhengzhou (CN)

(72) Inventors: Kai Tao, Zhengzhou (CN); Jian Zhao, Zhengzhou (CN); Youdao Wang, Zhengzhou (CN); Feng Guo, Zhengzhou (CN); Pengju Lu, Zhengzhou (CN); Yuanping Luo, Zhengzhou (CN); Xingjian He, Zhengzhou (CN); Zongshuai Jia, Zhengzhou (CN); Huijuan Zhao, Zhengzhou (CN); Xihui Wang, Zhengzhou (CN)

(21) Appl. No.: 19/091,304

(22) Filed: Mar. 26, 2025

(51) Int. Cl. G01R 31/58; G01N 27/04; G01R 15/20; G06Q 10/20

(52) U.S. Cl. CPC G01R 31/58; G01N 27/04; G01R 15/202; G06Q 10/20

(57) ABSTRACT

The present invention relates to the technical field of a cable terminal of a photovoltaic power station, and discloses a comprehensive detection and analysis apparatus for a cable terminal of a photovoltaic power station, including a base, where an upper surface of the base is fixedly provided with a fixed rod, a top of a moving rod is fixedly provided with a detector, an interior of the detector is provided with a detection and analysis system, a microbial monitoring module is configured to detect growth conditions and metabolic products of microorganisms on a cable surface and in a surrounding environment. In the technical solution combining electromagnetic induction monitoring and microbial growth feedback, real-time and accurate monitoring of a corrosion degree of the cable terminal of the photovoltaic power station is implemented, and dual effects of electromagnetic field changes and the microbial metabolites of the microorganisms are fully considered.

### TECHNICAL FIELD

The present invention relates to the technical field of a cable terminal of a photovoltaic power station, and in particular to a comprehensive detection and analysis apparatus for a cable terminal of a photovoltaic power station.

### BACKGROUND

During operation of a modern photovoltaic power station, a cable terminal, as a key power transmission component, has been under the combined action of a current, a voltage, and an environmental factor for a long time. If a corrosion problem of the cable terminal is not detected and effectively managed in time, it will lead to reduced device operation efficiency and even a fault. This not only affects power output, but also causes a possible safety hazard. Because the cable terminal is mainly located in a remote location of a power station, manual inspection is heavy and costly, and there is a lack of an efficient and real-time monitoring method.

At present, most existing cable terminal monitoring technologies rely on single physical quantity measurement, such as a temperature, a humidity, or a current intensity, which often provides only a surface state or current load information of a cable, and cannot fully understand an actual corrosion condition of the cable terminal. For example, although temperature monitoring can reflect a working state of a device, temperature monitoring cannot directly indicate a corrosion progress. A current change can provide some cable health information, but is greatly influenced by an external environment and current load fluctuations, resulting in inaccurate determining of the corrosion progress. These conventional methods usually fail to fully grasp comprehensive impact of corrosion of the cable terminal, which can easily lead to a delay and an error in corrosion detection.

In addition, corrosion caused by microorganisms plays an important role in the corrosion of the cable terminal, especially in a humid environment. In the prior art, microbial activities are less monitored, and an acceleration effect of metabolic products of the microorganisms on corrosion is usually ignored. Although some studies have begun to focus on the impact of the microorganisms, related technologies mainly concentrate on laboratory research and non-real-time experimental data, lacking solutions suitable for on-site real-time monitoring. Therefore, in the prior art, long-term impact of the microorganisms on cable corrosion cannot be effectively and timely monitored, so that a corrosion problem is usually discovered only after serious damage occurs, missing an optimal repair opportunity.

### SUMMARY

To overcome shortcomings in the prior art, the present invention provides a comprehensive detection and analysis apparatus for a cable terminal of a photovoltaic power station, which resolves problems of non-comprehensive monitoring, poor real-time performance, and incapability of effectively responding to microbial corrosion in the prior art.

To achieve the above purpose, the present invention is implemented by using the following technical solutions: a comprehensive detection and analysis apparatus for a cable terminal of a photovoltaic power station, including: a base, where a lower surface of the base is fixedly provided with universal wheels, an upper surface of the base is fixedly provided with a fixed rod, an interior of the fixed rod is slidably provided with a moving rod, a fixing bolt penetrates an interior of the moving rod, an outer wall of the fixing bolt is in threaded connection with the interior of the fixed rod, a top of the moving rod is fixedly provided with a detector, an interior of the detector is provided with a detection and analysis system, and the detection and analysis system includes the following modules:
an electromagnetic induction monitoring module, configured to detect a current and a magnetic field strength of the cable terminal, and calculate a corrosion degree of the cable terminal based on changes in the current and the magnetic field strength;
a microbial monitoring module, configured to detect growth conditions and metabolic products of microorganisms on a cable surface and in a surrounding environment;
a data processing module, configured to receive output data from the electromagnetic induction monitoring module and the microbial monitoring module, and predict a corrosion rate of the cable terminal in real time based on a feedback relationship between an electromagnetic field change and microbial growth;
a warning module, configured to issue a warning signal and provide a corresponding maintenance suggestion when the predicted corrosion rate exceeds a set threshold; and
an environmental regulation module, configured to adjust environmental factors such as a temperature and a humidity around the cable terminal based on real-time data.

Preferably, the electromagnetic induction monitoring module detects the current and the magnetic field strength of the cable terminal in real time by using a Hall effect sensor, and calculates the corrosion degree of the cable terminal according to a relationship between the electromagnetic field strength and the current and based on a magnetic field change caused by a current change, and the corrosion affects conduction efficiency of the current and the magnetic field strength.

Preferably, the microbial monitoring module monitors microbial activities on the cable surface and in the surrounding environment through an electrochemical sensor, including a quantity of the microorganisms and metabolic products of the microorganisms, and the metabolic products of the microorganisms have an impact on the corrosion rate of the cable surface.

Preferably, the data processing module calculates a corrosion progress of the cable terminal in real time in combination the data from the electromagnetic induction monitoring module and data from the microbial monitoring module by using a dynamic feedback model, further provides prediction of the corrosion rate, and outputs a warning signal.

Preferably, the warning module is based on the predicted corrosion rate, and when the corrosion rate exceeds the set threshold, automatically triggers the warning signal and provides the repair suggestion for reference by operation and maintenance personnel.

Preferably, the environmental regulation module automatically regulates various environmental factors such as a temperature, a humidity, ventilation, and the like based on timely detected microbial activities and environmental data, to optimize a working environment of the cable terminal and slow down microorganism growth and a corrosion progress.

Preferably, a relationship between the current and the magnetic field strength of the electromagnetic induction monitoring module reflects the corrosion degree of the cable terminal through the magnetic field change caused by a current change, and the corrosion degree is directly related to a resistance change and the corrosion rate on the cable surface.

A comprehensive detection and analysis method for a cable terminal of a photovoltaic power station includes the following steps:
first, detecting, by an electromagnetic induction monitoring module, a current and magnetic field strength of the cable terminal in real time, calculating a corrosion progress of the cable terminal, and evaluating the corrosion progress based on changes in the current and the magnetic field strength;
next, monitoring, by a microbial monitoring module, growth conditions and metabolic products of microorganisms on a cable surface and in a surrounding environment, and evaluating a corrosion rate based on changes in the metabolic products of the microorganisms; and
finally, fusing, by a data processing module, output data from the electromagnetic induction monitoring module and the microbial monitoring module, to predict the corrosion progress of the cable terminal in real time and provide a predicted value of the corrosion rate.

Preferably, the data processing module processes the data in real time through Kalman filtering and particle swarm optimization algorithms based on a feedback relationship between electromagnetic induction and microbial growth, to calculate the corrosion rate of the cable terminal and determine whether the corrosion rate exceeds a set threshold.

Preferably, when the predicted corrosion rate exceeds the set threshold, the warning module automatically issues a fault warning signal and provides a corresponding maintenance and repair suggestion to operation and maintenance personnel.

The present invention provides the comprehensive detection and analysis apparatus for a cable terminal of a photovoltaic power station, which has the following beneficial effects.

1. According to the present invention, in the technical solution combining electromagnetic induction monitoring and microbial growth feedback, real-time and accurate monitoring of the corrosion degree of the cable terminal of the photovoltaic power station is implemented. Compared with a solution in the prior art that relies solely on current or temperature changes, the present invention can comprehensively consider dual effects of electromagnetic field changes and metabolic products of microorganisms, overcoming a problem of poor accuracy of a conventional method in a complex environment.

2. According to the present invention, the environmental regulation module intelligently regulates environmental factors such as the temperature and the humidity of the cable terminal, to effectively suppress microbial growth, thereby slowing down a corrosion process. Unlike the solution in the prior art that relies solely on regular inspection and maintenance, the present invention provides a dynamic result mechanism that can respond in real time to environmental changes and prevent accelerated cable corrosion caused by the environmental factors.

3. According to the present invention, a multi-module collaborative working manner that combines electromagnetic induction, microbial monitoring, and data processing is provided, effectively improving the accuracy of corrosion rate prediction. Compared with a single monitoring manner in conventional technologies, multi-data fusion and a feedback mechanism of the present invention can provide a more comprehensive evaluation of a cable health state, resolving a problem of real-time and accurate monitoring that is difficult to achieve in a single technology.

4. According to the present invention, the intelligent warning module is used, the fault warning signal is automatically issued based on the real-time monitored data, and the corresponding repair suggestion is provided. Unlike conventional technologies that rely on manual inspection, the present invention can recognize a potential problem at an early stage and take preventive measures, greatly improving operation and maintenance efficiency of the photovoltaic power station and reducing downtime caused by a device fault.

### BRIEF DESCRIPTION OF DRAWINGS

FIG. 1 is a three-dimensional diagram of the present invention;

FIG. 2 is a schematic structural diagram of a base of the present invention;

FIG. 3 is a system block diagram of the present invention; and

FIG. 4 is a flow chart of a method of the present invention.

1. base; 2. universal wheel; 3. fixed rod; 4. moving rod; 5. fixing bolt; 6. detector.

### DESCRIPTION OF EMBODIMENTS

Technical solutions in embodiments of the present invention are clearly and completely described below with reference to accompanying drawings in the present invention. Apparently, the described embodiments are merely some rather than all of the embodiments of the present invention. All other embodiments obtained by a person of ordinary skill in the art based on the embodiments of the present invention without creative efforts shall fall within the protection scope of the present invention.

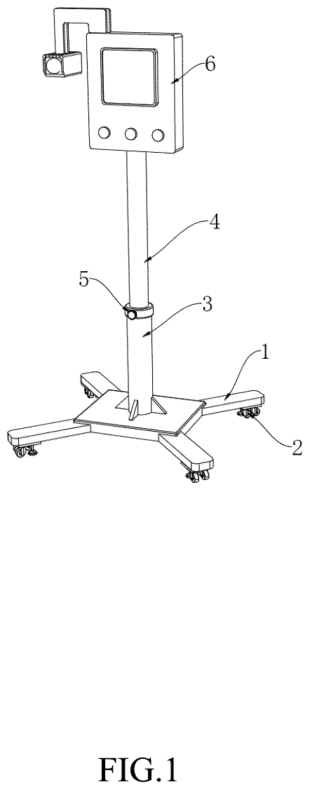

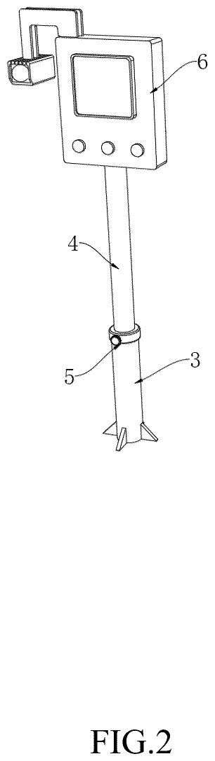

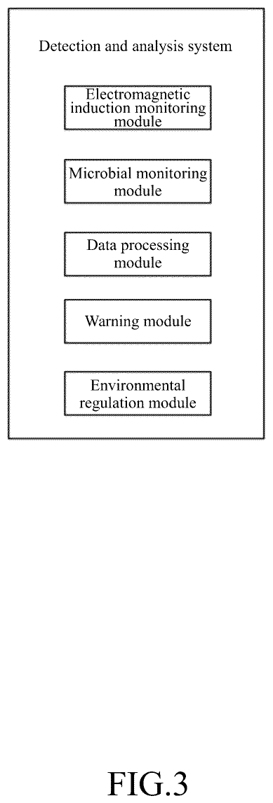

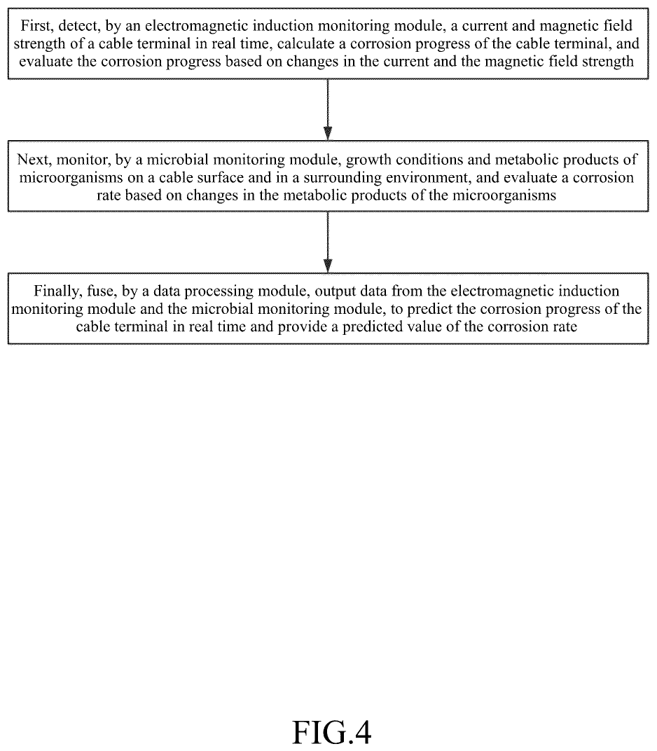

Refer to FIG. 1 to FIG. 4. Embodiments of the present invention provide a comprehensive detection and analysis apparatus for a cable terminal of a photovoltaic power station, including a base 1, where a lower surface of the base 1 is fixedly provided with universal wheels 2, an upper surface of the base 1 is fixedly provided with a fixed rod 3, an interior of the fixed rod 3 is slidably provided with a moving rod 4, a fixing bolt 5 penetrates an interior of the moving rod 4, an outer wall of the fixing bolt 5 is in threaded connection with the interior of the fixed rod 3, a top of the moving rod 4 is fixedly provided with a detector 6, and an interior of the detector 6 is provided with a detection and analysis system. The detection and analysis system includes the following modules:
an electromagnetic induction monitoring module, configured to detect a current and a magnetic field strength of the cable terminal, and calculate a corrosion degree of the cable terminal based on changes in the current and the magnetic field strength;
a microbial monitoring module, configured to detect growth conditions and metabolic products of microorganisms on a cable surface and in a surrounding environment;
a data processing module, configured to receive output data from the electromagnetic induction monitoring module and the microbial monitoring module, and predict a corrosion rate of the cable terminal in real time based on a feedback relationship between an electromagnetic field change and microbial growth;
a warning module, configured to issue a warning signal and provide a corresponding maintenance suggestion when the predicted corrosion rate exceeds a set threshold; and
an environmental regulation module, configured to adjust environmental factors such as a temperature and a humidity around the cable terminal based on real-time data.

### Base and Moving System

A foundation of the apparatus is the base 1, and the lower surface of the base is fixedly provided with the universal wheels 2, so that the entire apparatus can move freely within the photovoltaic power station. The design of the universal wheels provides flexibility, so that a position of the apparatus can be easily adjusted to be accurately aligned with the cable terminal to be detected. In this movement manner, an operator can prevent frequent disassembly or unnecessary intervention of the cable terminal, greatly improving work efficiency.

The upper surface of the base 1 is fixedly provided with the fixed rod 3, the fixed rod serves to provide support for the moving rod 4, allowing the detector 6 to move in a vertical direction to be adapted to cable terminals of different heights. Sliding design inside the fixed rod 3 ensures that the moving rod 4 can move smoothly up and down, thereby being accurately aligned with an area to be detected.

### Electromagnetic Induction Monitoring Module

The electromagnetic induction monitoring module is responsible for monitoring the current and the magnetic field strength of the cable terminal in real time and calculating the corrosion degree of the cable terminal. A relationship between the current and the magnetic field strength is extremely close, and a magnetic field is generated when a current flows through a cable. As the corrosion on the surface of the cable intensifies, the efficiency of current conduction decreases, resulting in a change in the magnetic field strength. The electromagnetic induction monitoring module collects current and magnetic field data through a Hall effect sensor in real time, and calculates the corrosion degree of the cable based on the data.

The corrosion degree is calculated according to the relationship between the change in the magnetic field strength and the current and based on the magnetic field change caused by the current change. During this process, the corrosion degree directly affects a resistance of the cable, further affecting the efficiency of current conduction. This change is monitored in real time, so that the apparatus can accurately determine a corrosion condition of the cable terminal, providing accurate data support for operation and maintenance personnel.

### Microbial Monitoring Module

The corrosion of the cable terminal is not only caused by a physical factor, but also closely related to the growth of microorganisms in the environment. The microbial monitoring module monitors microbial activities on the cable surface and a surrounding environment through the electrochemical sensor. The growth and metabolic products (such as acidic substances) of the microorganisms accelerate a process of metal corrosion. Therefore, monitoring metabolic activities of the microorganisms is of great significance for determining the intensification of corrosion.

A working principle of the microbial monitoring module is to detect a quantity and metabolic products of the microorganisms in real time through the electrochemical sensor, and evaluate a corrosion rate based on changes in the metabolic products. The metabolic products of the microorganisms can reduce a resistance of the cable surface and accelerate the corrosion process. The microbial monitoring module can provide reliable basis for early warning of the corrosion of the cable terminal by continuously monitoring the microbial activities.

### Data Processing Module

The data processing module fuses data collected by the electromagnetic induction monitoring module and the microbial monitoring module, to predict the corrosion rate of the cable terminal in real time. In combination with a feedback relationship between the electromagnetic field change and the microbial growth, the data processing module can accurately calculate the corrosion process and output a predicted value of the corrosion rate.

The data processing module performs real-time calculation by using a dynamic feedback model and in combination with electromagnetic field data and microbial activity data. Such data not only helps evaluate a current health state of the cable terminal, but also can predict a corrosion trend for a period of time in the future. Through these predictions, the system can detect a potential problem in advance, prevent a cable fault caused by corrosion, and reduce maintenance costs for the photovoltaic power plant.

### Warning Module

When the corrosion rate predicted by the data processing module exceeds the set threshold, the warning module automatically triggers a warning signal. A function of the warning module is to timely provide a warning to the operation and maintenance personnel and suggest a corresponding maintenance operation. The warning module is designed to effectively reduce a fault of the cable terminal caused by corrosion, ensuring that the photovoltaic power station is always in a safe state during operation and maintenance.

### Environmental Regulation Module

The environmental regulation module automatically adjusts various environmental factors such as a temperature, a humidity, ventilation, and the like based on timely detected microbial activities and environmental data, to optimize the working environment of the cable terminal. The environmental regulation module can optimize growth conditions of the microorganisms by adjusting the temperature and humidity around the cable terminal, thus slowing down the corrosion progress.

Specifically, the environmental regulation module can control the temperature and the humidity around the cable, to reduce electrical short circuits and corrosion caused by moisture, and maintain stable operation of the cable terminal of the photovoltaic power station. The environmental regulation module is designed to help improve the service life of the power station device and reduce maintenance costs caused by an environmental change.

The electromagnetic induction monitoring module of the present invention is a key component of the comprehensive detection and analysis apparatus for a cable terminal of a photovoltaic power station. A main function of the electromagnetic induction monitoring module is to calculate the corrosion degree of the cable terminal by real-time detection of the current and the magnetic field strength. Through the function of the electromagnetic induction monitoring module, the present invention can accurately evaluate the corrosion state of the cable terminal and issue a warning at an early stage of the corrosion progress. An implementation method for the electromagnetic induction monitoring module is to implement real-time monitoring of a health state of the cable terminal based on a physical relationship between the current and the electromagnetic field strength and in combination with an electromagnetic induction principle and a corrosion-induced resistance change model.

In this embodiment, the electromagnetic induction monitoring module detects the current and the magnetic field strength of the cable terminal in real time through a Hall effect sensor. The Hall effect sensor can accurately sense a current change in a cable, thereby generating a magnetic field related to a current strength around the cable terminal. A strength of the magnetic field changes with a corrosion condition of the cable, thereby affecting the efficiency of current conduction. The increase in a cable resistance caused by corrosion directly affects a current-flowing capacity, and in turn affects the magnetic field strength. Therefore, the corrosion degree of the cable can be effectively calculated by detecting a magnetic field change in real time.

In a specific implementation, the electromagnetic induction monitoring module performs corrosion detection based on a relationship between the current change and the magnetic field strength. When the current flows through the cable, according to Ampere's law of loops and Faraday's law of electromagnetic induction, the current strength is closely related to a resistance of the cable, and corrosion of the cable increases the resistance of the cable. The increase in the resistance leads to a decrease in the efficiency of current flow, resulting in a change in the magnetic field strength. Therefore, the change in the magnetic field strength is directly proportional to the corrosion degree of the cable.

In a possible implementation, the electromagnetic induction monitoring module calculates the corrosion degree of the cable terminal using the following formula:

$$B ( t ) = {μ}_{0} \cdot \frac{I ( t )}{2 π r} ( 1 + k \cdot C ( t ) )$$

where B(t) is the magnetic field strength (unit: Tesla, T), I(t) is the current strength (unit: Ampere, A), r is a distance from the cable surface to a magnetic field measurement point (unit: meter, m), μ₀ is a vacuum magnetic permeability (unit: Henry per meter, H/m), C(t): is the corrosion degree of the cable (dimensionless, with a value range of 0 to 1), and k is a corrosion-electromagnetic coupling coefficient (dimensionless).

In some embodiments, the increase in corrosion is not only manifested as a change in the current strength, but may also generate a local change in the electric field on the cable surface. Specifically, corrosion usually leads to locally uneven damage on the cable surface, and the damage may cause a change in a transmission path of the current, thereby changing the distribution of the current and a shape of the magnetic field. This change can be captured by a highly sensitive Hall effect sensor and directly correlated with intensification of a corrosion progress. The electromagnetic induction monitoring module can more accurately calculate the corrosion rate on the cable surface by using this change.

Alternatively, the electromagnetic induction monitoring module can further improve detection accuracy by linking a temperature sensor with the electromagnetic field strength. The temperature has an impact on conductivity of the current. Therefore, during corrosion, a temperature change may influence the current change. The electromagnetic induction monitoring module can eliminate the interference of the temperature change on current conduction efficiency through a temperature compensation algorithm, further improving the accuracy of calculating the corrosion degree.

In some embodiments, the electromagnetic induction monitoring module can also work in conjunction with the microbial monitoring module. The microbial monitoring module can monitor growth conditions and metabolic products of the microorganisms on the cable surface in real time. The microbial activities are a key factor in accelerating corrosion. The system can obtain more comprehensive information at an early stage of corrosion by fusing data from the microbial monitoring module and data from the electromagnetic induction monitoring module, thereby improving the accuracy of warning.

In this embodiment, an advantage of the electromagnetic induction monitoring module is an efficient and non-contact monitoring manner, which can reflect a corrosion state of the cable terminal in real time. In large-scale operation and maintenance of the photovoltaic power station, automatic and real-time cable terminal health monitoring can be implemented through the electromagnetic induction monitoring module, preventing regular shutdown for inspection in a conventional method. The reliability of the power station device can be significantly improved, and maintenance costs can be reduced under continuous monitoring by the electromagnetic induction monitoring module.

The microbial monitoring module performs real-time monitoring by using an electrochemical sensor. The electrochemical sensor is capable of capturing a quantity and metabolic products of the microorganisms on the cable surface and a surrounding environment. Specifically, the metabolic products of the microorganisms, especially acidic substances, significantly accelerate the corrosion of the cable surface. A relationship between the quantity and the metabolic products of the microorganisms is closely related to the corrosion rate of the cable. As the microorganisms grow, the metabolic products erode metal on the cable surface, causing a change in a cable's resistance and further accelerating the corrosion process.

In general, the growth of the microorganisms directly affects the corrosion rate. As microbial activity is stronger, the corrosion rate is usually higher. In this case, the electrochemical sensor can evaluate the growth conditions of the microorganisms by measuring a change in conductivity. The change in conductivity reflects a change in a concentration of the metabolic products of the microorganisms, while the concentration of the metabolic products reflects the intensification of corrosion. Acidic metabolic products of the microorganisms, such as acids or sulfides, can significantly change an electrical conductivity of the cable surface, increasing conductivity of the cable surface. This change is fed back through sensor measurement, providing data support for calculation of the corrosion rate.

Alternatively, the microbial monitoring module can further evaluate an impact on the corrosion rate by directly monitoring a category and growth states of the microorganisms on the cable surface. In this implementation, the microbial monitoring module not only detects the quantity of the microorganisms, but also analyzes adhesion of the microorganisms on the cable surface by using an image processing technology. In this manner, the microbial monitoring module can more accurately determine the corrosion state because a growth shape of the microorganisms on the cable surface is closely related to corrosiveness of the microorganisms.

The work of the microbial monitoring module mainly includes the following aspects: first, the electrochemical sensor reflects changes in the concentration of the metabolic products caused by the microbial activities by real-time detection of the conductivity of the cable surface; second, the microbial monitoring module calculates the impact of the microbial activity on the corrosion rate of the cable surface.

This process is usually implemented through the following mathematical model:

$${V}_{corrosion} ( t ) = α \cdot {( \frac{N ( t )}{K} )}^{γ} \cdot f ( E )$$

where V_{corrosion}(t) is the corrosion rate (unit: meter/second, m/s), N(t) is the quantity of the microorganisms (unit: individual number), K is an environmental carrying capacity (unit: individual number), α is a correlation coefficient between the microorganisms and the corrosion rate (unit: meter/second), γ is a non-linear coefficient (dimensionless), and f(E) is an environmental factor function, reflecting the influence of environmental factors such as the temperature, the humidity, and an oxygen concentration on the corrosion rate.

Through this formula, the microbial monitoring module can calculate the corrosion rate of the cable terminal in real time in combination with a relationship among the quantity of the microorganisms, the environmental factors, and the corrosion rate. A nonlinear relationship between the microbial metabolic activities and the corrosion rate enables the microbial monitoring module to be highly adaptable and be capable of handling corrosion conditions of different cable surfaces and microbial growth conditions.

In a possible implementation, the microbial monitoring module can also work in conjunction with the electromagnetic induction monitoring module, to further improve accurate prediction of the corrosion progress by fusing electromagnetic field data and microbial data. This synergistic effect enables the apparatus to not only determine the corrosion degree based on the current and the magnetic field strength, but also dynamically adjust the corrosion rate by using the microbial activities, improving overall monitoring accuracy.

Specifically, the electromagnetic induction monitoring module determines a basic condition of cable corrosion by detecting changes in the magnetic field, while the microbial monitoring module provides additional information by detecting the microbial activities, providing more comprehensive prediction of the corrosion process. The influence of the microorganisms is not limited to the quantity, but also involves a type of the microorganisms and a type and concentration of the metabolic products. Through comprehensive analysis of the electrochemical sensor, the microbial monitoring module can provide real-time data to help the system make more accurate corrosion evaluation.

In some embodiments, the microbial monitoring module may also be calibrated through a temperature and humidity compensation algorithm. This is because environmental conditions, especially the humidity and the temperature, directly affect a growth rate of the microorganisms and the production of the metabolic products. These parameters are automatically adjusted, so that the microbial monitoring module can eliminate the impact of environmental changes on a detection result and ensure data accuracy.

In summary, the microbial monitoring module provides effective evaluation of the corrosion rate through real-time monitoring of the microorganisms on the surface of the cable terminal. The microbial monitoring module provides reliable health monitoring for the cable terminal of the photovoltaic power station in combination with a relationship among conductivity changes, concentrations of the metabolic products of the microorganisms, the environmental factors, and the corrosion rate. Through the microbial monitoring module, the corrosion problem can be effectively found at an early stage, thus providing support for preventive maintenance and operation optimization of the power station.

The data processing module fuses real-time data from the electromagnetic induction monitoring module and real-time data from the microbial monitoring module, and performs calculation by using a dynamic feedback model. A core objective of this process is to evaluate an overall health state of the cable terminal and calculate a trend of the corrosion progress of the cable terminal. Specifically, the data processing module dynamically calculates the corrosion rate through a mathematical model in combination with a plurality of variables such as the current, the magnetic field strength, and the quantity and the metabolic products of the microorganisms, and predicts the development of corrosion.

In general, the data processing module performs further processing in combination with data of the metabolic products provided by the microbial monitoring module and based on change data of the current and the magnetic field strength provided by the electromagnetic induction monitoring module. Output data of the two modules can jointly reflect a degree and intensification rate of corrosion of the cable terminal. Due to a direct impact of the metabolic products of the microorganisms on the corrosion progress, the role of the data processing module is not only to combine a change in the current with a change in the magnetic field strength, but also to provide real-time compensation based on changes in microbial metabolite concentrations of the microorganisms.

Alternatively, the data processing module fuses electromagnetic induction data and microbial activity data by using a nonlinear dynamic feedback model, to derive the corrosion rate. According to the model, real-time calculation is performed based on the following formula:

$${V}_{corrosion} ( t ) = α \cdot {( \frac{N ( t )}{K} )}^{γ} \cdot f ( E ) + β \cdot B ( t )$$

where V_{corrosion}(t) is the corrosion rate (unit: meter/second), N(t) is the t) quantity of the microorganisms (unit: individual number), K is an environmental carrying capacity (unit: individual number), α is a correlation coefficient between the microorganisms and the corrosion rate (unit: meter/second), γ is a nonlinear coefficient (dimensionless), f(E) is an environmental factor function, reflecting the influence of external conditions such as the temperature and humidity on the corrosion rate, B(t) is the electromagnetic field strength (unit: Tesla, T), and β is a coupling coefficient between the electromagnetic field and the corrosion rate (unit: meter/second).

Through this formula, the data processing module analyzes growth data of the microorganisms and data of the electromagnetic induction, and calculates the corrosion rate in real time. The nonlinear relationship between the quantity of the microorganisms N(t) and the corrosion rate indicates that a metabolic product rate of the microorganisms is dynamically interacting with the corrosion rate. Therefore, it is necessary to comprehensively consider a combined effect of the quantity of the microorganisms and the metabolic product rate of the microorganisms on the corrosion rate. In a possible implementation, the data processing module can further optimize prediction of the corrosion rate in combination with environmental factors f(E) such as the temperature, the humidity, the oxygen concentration, and other external conditions. Specifically, the temperature and the humidity have a significant impact on the growth of the microorganisms, and changes in the environmental conditions can cause a fluctuation in a microbial activity level. Therefore, the data processing module dynamically adjusts microbial factors in the model based on changes in environmental data to ensure the accuracy of a calculation result.

Specifically, the data processing module calculates the corrosion progress of the cable terminal based on a dynamic feedback model, and generates corrosion prediction reports in combination with real-time monitored data. These reports not only provide a current state of corrosion, but also anticipate a future corrosion rate, providing an important basis for subsequent maintenance decision-making.

In some embodiments, the data processing module also uses an adaptive algorithm to continuously optimize prediction accuracy. As operation time of the device increases, the system accumulates more monitored data. Through continuous data training, the data processing module can perform self-adjustment based on an actual environment and actual performance of the cable terminal, improving the accuracy of corrosion rate prediction.

Overall, the data processing module, as a core component of the present invention, fuses data from the electromagnetic induction monitoring module and data from the microbial monitoring module, providing a high-precision calculation result for predicting the corrosion rate. The data processing module can not only evaluate the corrosion progress of the cable terminal based on real-time data, but also optimize a parameter of the model through an adaptive algorithm, to ensure accurate and reliable prediction results in different environments, providing strong support for maintenance of the cable terminal and operation of the photovoltaic power station.

The warning module mainly determines the health state of the cable terminal in real time by receiving a predicted value of the corrosion rate output by the data processing module. When the corrosion rate V_{corrosion}(t) calculated by the system exceeds a preset safety threshold, the warning module issues an alarm signal to prompt the operation and maintenance personnel to perform maintenance or repair.

Specifically, the warning module not only provides a simple alarm prompt, but also provides a repair suggestion in combination with a current corrosion situation, helping the operation and maintenance personnel take corresponding measures based on a specific condition.

In general, the warning module monitors and analyzes the corrosion rate in real time based on the threshold set by the system. The threshold is usually set in consideration with a working condition of the cable terminal of the photovoltaic power station, an environmental change, and a characteristic of a cable material. In the case of an excessive corrosion rate, the warning module activates an alarm program to remind a user to check the device timely and perform a maintenance task.

Alternatively, the warning module can also provide a future prediction by analyzing a historical data trend of the corrosion rate. For example, when the corrosion rate tends to increase and cannot be restored to a safe range, the warning module can notify the user in advance of performing a more comprehensive cable terminal inspection or taking replacement measures. This process helps the operation and maintenance personnel make more timely and informed decision-making in combination with data analysis, a predictive model, and historical data.

Specifically, working of the warning module can be described through the following formula:

$$Alert ( t ) = \{ \begin{matrix}1 & if {V}_{corrosion} ( t ) > {V}_{threshold} \\ 0 & if {V}_{corrosion} ( t ) \leq {V}_{threshold}\end{matrix}$$

where Alert(t) is an output of the warning signal (unit: dimensionless, 1 represents warning, 0 represents normal), V_{corrosion}(t) is a real-time corrosion rate (unit: meter/second, m/s), and V_{threshold} is a set corrosion rate threshold (unit: meter/second, m/s).

When the real-time corrosion rate V_{corrosion}(t) exceeds a set threshold V_{threshold}, the warning module issues an alarm signal. This threshold is usually adjusted based on an operation state of the device and durability of the cable material. Specifically, when the corrosion rate of the cable terminal exceeds a value, it may lead to a decrease in power transmission efficiency or a more serious fault. Timely alarming from the warning module can help reduce downtime of the photovoltaic power station and ensure safety and stability of the power station.

In a possible implementation, the warning module not only issues a single alarm signal, but also can predict a possible future fault in combination with historical data of the device. For example, the warning module can calculate a trend of the corrosion rate for a period of time in the future based on historical corrosion data of the cable terminal, and then predict whether the corrosion rate exceeds the threshold. The system can notify, through this predictive mechanism, the operation and maintenance personnel in advance of assisting in preventive maintenance.

In some embodiments, the warning module can also provide different levels of maintenance recommendations based on different corrosion degrees. For example, when the corrosion rate slightly exceeds a standard, the system may recommend routine inspections; or when the corrosion rate is high, the system may recommend to immediately shut down for inspection or replace the cable terminal. In this way, the operation and maintenance personnel can schedule resources reasonably based on specific warning information to prevent a fault in the power station.

In general, the warning module can monitor the corrosion rate in real time and perform prediction based on historical data, to timely issue the warning signal and provide an accurate repair suggestion for the operation and maintenance personnel. Health monitoring of the cable terminal in the photovoltaic power station is effectively ensured by using the warning module, reducing a risk of a device fault caused by corrosion and improving the operation efficiency and safety of the power station.

The environmental regulation module monitors environmental factors such as the temperature, the humidity, and the oxygen concentration in real time based on the data output from the microbial monitoring module and from the electromagnetic induction monitoring module, and optimizes working conditions of the cable terminal by adjusting the environmental parameters. Corrosion is usually a result of a plurality of factors working jointly, and changes in the temperature and the humidity, the oxygen concentration, and the microbial activity may all affect the corrosion rate of the cable terminal. The environmental regulation module can significantly slow down the corrosion rate of the cable by automatically adjusting these factors.

In general, an increase in the temperature and the humidity promotes the growth of the microorganisms, and the metabolic products of the microorganisms accelerate the corrosion of the cable surface. Therefore, maintaining the temperature and the humidity within a proper range is the key to controlling corrosion. Alternatively, the environmental regulation module can automatically adjust the temperature and the humidity based on the data provided by the microbial monitoring module, to ensure that the environment is not extremely humid and reduce breeding space for the microorganisms, thereby slowing down the corrosion progress.

Specifically, the environmental regulation module monitors the environment around the cable terminal in real time by using a temperature and humidity control device. When a temperature or humidity is monitored to exceed a safe range, the environmental regulation module automatically adjusts a working state of an air conditioner or a humidifier/dehumidifier to maintain an optimal environmental condition. In addition, the environmental regulation module can also adjust air circulation and increase an oxygen content in a cable area through a ventilation device, to prevent an oxidation reaction from further intensifying the corrosion process.

In a possible implementation, the environmental regulation module can comprehensively consider a plurality of environmental factors (such as the temperature, the humidity, the oxygen concentration, and the like), and automatically perform self-regulation based on real-time data of these factors. In this case, the environmental regulation module not only relies on the data from the microbial monitoring module, but also fuses predicted corrosion rate data output from the electromagnetic induction monitoring module and the data processing module, to determine whether the environmental parameters are to be adjusted.

In some embodiments, the environmental regulation module optimizes environmental control through an intelligent algorithm. For example, when the corrosion rate output by the data processing module approaches or exceeds the set threshold, the environmental regulation module responds quickly and adjusts the environmental condition, so that the microbial activity is effectively inhibited, thereby reducing the corrosion rate. Specifically, the environmental regulation module can adjust air flow and the humidity around the cable based on trends of temperature and humidity changes and according to preset regulation rules, to prevent a cable short circuit or current loss caused by a humid environment.

Alternatively, the environmental regulation module can also automatically adjust a working state of another device in the photovoltaic power station in combination with an overall management system of the photovoltaic power station. For example, when humidities in some areas are extremely high, the environmental regulation module can help maintain a proper environmental temperature and humidity in combination with other systems, such as a dehumidification device or a temperature control device. Through this collaborative regulation, it is ensured that the working environment of the cable terminal is always in an optimal state, thereby delaying the occurrence of corrosion.

Specifically, a workflow of the environmental regulation module includes the following aspects:
collecting temperature and humidity data around the cable terminal through a sensor, as well as an oxygen concentration in the air in real time;
evaluating a current corrosion risk based on data from the electromagnetic induction monitoring module and the microbial monitoring module;
automatically activating, when the corrosion rate is extremely fast, an adjustment system to adjust environmental factors such as the temperature, the humidity, and the ventilation;
predicting, by the module when needed, a future corrosion risk based on a trend of environmental changes and taking measures in advance to optimize the environment.

Refer to FIG. 1 to FIG. 4. Embodiments of the present invention provide a comprehensive detection and analysis method for a cable terminal of a photovoltaic power station, including the following steps:
first, detecting, by an electromagnetic induction monitoring module, a current and magnetic field strength of the cable terminal in real time, calculating a corrosion progress of the cable terminal, and evaluating the corrosion progress based on changes in the current and the magnetic field strength;
next, monitoring, by a microbial monitoring module, growth conditions and metabolic products of microorganisms on a cable surface and in a surrounding environment, and evaluating a corrosion rate based on changes in the metabolic products of the microorganisms; and
finally, fusing, by a data processing module, output data from the electromagnetic induction monitoring module and the microbial monitoring module, to predict the corrosion progress of the cable terminal in real time and provide a predicted value of the corrosion rate.

The data processing module processes data in real time through Kalman filtering and particle swarm optimization algorithms based on the feedback relationship between electromagnetic induction and microbial growth, to calculate the corrosion rate of the cable terminal and determine whether the corrosion rate exceeds a set threshold.

When the predicted corrosion rate exceeds the set threshold, the warning module automatically issues a fault warning signal and provides a corresponding maintenance and repair suggestion to operation and maintenance personnel.

Working principle: the apparatus can be easily moved to a position of the cable terminal to be detected through the universal wheel 2, the upper surface of the base 1 is fixedly provided with the fixed rod 3, the fixed rod 3 adjusts a height of the apparatus through the sliding moving rod 4, to ensure that the detector 6 can accurately align with the cable terminal for detection, the moving rod 4 is internally threaded with the fixing bolt 5, the bolt 5 is connected to the fixed rod 3 to control a height and position of the moving rod 4 and to ensure stable operation of the device, the fixing bolt 5 is connected to an internal thread of the fixed rod 3 through a thread on an outer wall of the fixing bolt 5, to facilitate position adjustment and fixing, the detector 6 is fixed at the top of the moving rod 4 and is internally provided with the detection and analysis system for performing detection and data analysis on the cable terminal. The detection and analysis system includes the electromagnetic induction monitoring module, the microbial monitoring module, the data processing module, the warning module, and the environmental regulation module, which work together to monitor the corrosion state of the cable terminal.

During operation, the electromagnetic induction monitoring module detects changes in the current and the magnetic field strength in real time, and calculates the corrosion degree of the cable terminal based on the changes in the current and the magnetic field strength. Corrosion leads to a decrease in current conduction efficiency and a change in the magnetic field strength, thereby affecting measured data of the electromagnetic induction monitoring module. The microbial monitoring module monitors microbial activities on the cable surface and in the surrounding environment through an electrochemical sensor, including a quantity of and metabolic products of the microorganisms. The metabolic products of the microorganisms have an impact on the corrosion rate of the cable surface. The data processing module fuses data from the electromagnetic induction monitoring module and data from the microbial monitoring module, calculates a corrosion progress of the cable terminal in real time through a dynamic feedback model, provides a predicted value of the corrosion rate, and evaluates a health state of the cable terminal in combination with a feedback relationship between the electromagnetic field change and microbial growth.

When the data processing module calculates that the corrosion rate exceeds a set threshold, the warning module triggers a warning signal to prompt operation and maintenance personnel to take proper repair or maintenance measures, ensuring normal operation of a photovoltaic power station system. The environmental regulation module automatically adjusts a temperature, a humidity, and other environmental factors around the cable terminal based on real-time detected data of microbial activities and environmental data, optimizes growth conditions of the microorganisms, and slows down the corrosion progress. The base 1 and the universal wheel 2 are provided, so that the device can be easily moved to a position to be detected in the power station. The moving rod 4 is adjusted to ensure that the detector 6 performs accurate detection on the cable terminal, implementing comprehensive health monitoring and timely warning of the cable terminal.

Although embodiments of the present invention have been shown and described, it can be understood that a person of ordinary skill in the art can perform various variations, modifications, substitutions, and variants on these embodiments without departing from the principle and spirit of the present invention, and the scope of the present invention is limited by attached claims and equivalents thereof.

What is claimed is:

1. A comprehensive detection and analysis apparatus for a cable terminal of a photovoltaic power station, comprising a base (1), wherein a lower surface of the base (1) is fixedly provided with universal wheels (2), an upper surface of the base (1) is fixedly provided with a fixed rod (3), an interior of the fixed rod (3) is slidably provided with a moving rod (4), a fixing bolt (5) penetrates an interior of the moving rod (4), an outer wall of the fixing bolt (5) is in threaded connection with the interior of the fixed rod (3), a top of the moving rod (4) is fixedly provided with a detector (6), an interior of the detector (6) is provided with a detection and analysis system, and the detection and analysis system comprises the following modules:
an electromagnetic induction monitoring module, configured to detect a current and a magnetic field strength of the cable terminal, and calculate a corrosion degree of the cable terminal based on changes in the current and the magnetic field strength;
a microbial monitoring module, configured to detect growth conditions and metabolic products of microorganisms on a cable surface and in a surrounding environment;
a data processing module, configured to receive output data from the electromagnetic induction monitoring module and the microbial monitoring module, and predict a corrosion rate of the cable terminal in real time based on a feedback relationship between an electromagnetic field change and microbial growth;
a warning module, configured to issue a warning signal and provide a corresponding maintenance suggestion when the predicted corrosion rate exceeds a set threshold; and
an environmental regulation module, configured to adjust environmental factors such as a temperature and a humidity around the cable terminal based on real-time data.

2. The comprehensive detection and analysis apparatus for a cable terminal of a photovoltaic power station according to claim 1, wherein the electromagnetic induction monitoring module detects the current and the magnetic field strength of the cable terminal in real time by using a Hall effect sensor, and calculates the corrosion degree of the cable terminal according to a relationship between the electromagnetic field strength and the current and based on a magnetic field change caused by a current change, and the corrosion affects conduction efficiency of the current and the magnetic field strength.

3. The comprehensive detection and analysis apparatus for a cable terminal of a photovoltaic power station according to claim 1, wherein the microbial monitoring module monitors microbial activities on the cable surface and in the surrounding environment through an electrochemical sensor, comprising a quantity of the microorganisms and metabolic products of the microorganisms, and the metabolic products of the microorganisms have an impact on the corrosion rate of the cable surface.

4. The comprehensive detection and analysis apparatus for a cable terminal of a photovoltaic power station according to claim 1, wherein the data processing module calculates a corrosion progress of the cable terminal in real time in combination the data from the electromagnetic induction monitoring module and data from the microbial monitoring module by using a dynamic feedback model, further provides prediction of the corrosion rate, and outputs a warning signal.

5. The comprehensive detection and analysis apparatus for a cable terminal of a photovoltaic power station according to claim 1, wherein the warning module is based on the predicted corrosion rate, and when the corrosion rate exceeds the set threshold, automatically triggers the warning signal and provides the repair suggestion for reference by operation and maintenance personnel.

6. The comprehensive detection and analysis apparatus for a cable terminal of a photovoltaic power station according to claim 1, wherein the environmental regulation module automatically regulates various environmental factors such as a temperature, a humidity, ventilation, and the like based on timely detected microbial activities and environmental data, to optimize a working environment of the cable terminal and slow down microorganism growth and a corrosion progress.

7. The comprehensive detection and analysis apparatus for a cable terminal of a photovoltaic power station according to claim 1, wherein a relationship between the current and the magnetic field strength of the electromagnetic induction monitoring module reflects the corrosion degree of the cable terminal through the magnetic field change caused by a current change, and the corrosion degree is directly related to a resistance change and the corrosion rate on the cable surface.

8. A comprehensive detection and analysis method for a cable terminal of a photovoltaic power station, applied to the comprehensive detection and analysis apparatus for a cable terminal of a photovoltaic power station according to claim 1, comprising the following steps:
first, detecting, by an electromagnetic induction monitoring module, a current and magnetic field strength of the cable terminal in real time, calculating a corrosion progress of the cable terminal, and evaluating the corrosion progress based on changes in the current and the magnetic field strength;
next, monitoring, by a microbial monitoring module, growth conditions and metabolic products of microorganisms on a cable surface and in a surrounding environment, and evaluating a corrosion rate based on changes in the metabolic products of the microorganisms; and
finally, fusing, by a data processing module, output data from the electromagnetic induction monitoring module and the microbial monitoring module, to predict the corrosion progress of the cable terminal in real time and provide a predicted value of the corrosion rate.

9. The comprehensive detection and analysis method for a cable terminal of a photovoltaic power station according to claim 7, wherein the data processing module processes data in real time through Kalman filtering and particle swarm optimization algorithms based on the feedback relationship between electromagnetic induction and microbial growth, to calculate the corrosion rate of the cable terminal and determine whether the corrosion rate exceeds a set threshold.

10. The comprehensive detection and analysis method for a cable terminal of a photovoltaic power station according to claim 7, wherein when the predicted corrosion rate exceeds the set threshold, the warning module automatically issues a fault warning signal and provides a corresponding maintenance and repair suggestion to operation and maintenance personnel.
